(19) United States
(12) Patent Application Publication
(10) Pub. No.: US 2025/0371681 A1
(43) Pub. Date: Dec. 4, 2025

(54) METHOD AND DEVICE FOR PROVIDING MRI IMAGES RELATING TO AT LEAST ONE PART OF A PATIENT'S BODY WITH REDUCED CONTRAST AGENT ADMINISTRATION

(71) Applicant: relios.vision GmbH, Bonn (DE)

(72) Inventors: Alexander Radbruch, Bonn (DE); Alexander Effland, Bonn (DE)

(73) Assignee: relios.vision GmbH, Bonn (DE)

(21) Appl. No.: 18/873,087

(22) PCT Filed: Jun. 9, 2023
(86) PCT No.: PCT/EP2023/065489

§ 371 Date: Dec. 9, 2024

(30) Foreign Application Priority Data
Jun. 9, 2022 (EP) 22177992.9

(51) Int. Cl. G06T 5/70; G01R 33/56; G06T 5/50; G06T 5/94; G06T 7/30

(52) U.S. Cl. CPC G06T 5/70; G01R 33/5601; G06T 5/50; G06T 5/94; G06T 7/30; G06T 2207/10088; G06T 2207/20081; G06T 2207/20084

(57) ABSTRACT

The invention relates to a method and a device (1) for providing MRI images relating to at least one part of a patient's body with reduced contrast medium administration. The device (1) has input means for obtaining MRI images relating to at least one part of a patient's body without contrast medium administration, ⋅input means for obtaining MRI images with respect to at least the part of the patient's body with contrast agent administration, wherein the contrast agent administration allowed for the body part is reduced by at least 50% compared to a conventional MRI image, ⋅means for image registration of the MRI images without contrast medium administration and of the MRI images with contrast medium administration, wherein the means for image registration operate in three-dimensional space, ⋅means for producing at least one subtraction image from the comparison of image-registered MRI images without contrast medium administration and image-registered MRI images with contrast medium administration, ⋅means for contrast enhancement based on the subtraction image and the image-registered MRI images without contrast agent administration or with reduced contrast agent administration, wherein the means for contrast enhancement based on a trained neural network provide both enhancement and artefact reduction by means of a non-linear transformation, wherein the means for contrast enhancement are arranged to produce a de-noised contrast enhanced difference image, ⋅wherein three-dimensional data are used throughout, and the image registration means provide rigid body registration in three dimensions. The invention also relates to a computer program product and the use of the method and devices according to the invention.

### CROSS-REFERENCE TO RELATED APPLICATIONS

This application claims priority to International Application No. PCT/EP2023/065489, filed on Jun. 9, 2023, which claims the priority benefit of European Patent Application No. EP 22177992.9, filed on Jun. 9, 2022. The contents of the above identified applications are incorporated herein by reference in their entirety.

### BACKGROUND

Magnetic resonance imaging (MRI for short) is used for diagnosis in many areas of human and veterinary medicine.

Magnetic resonance imaging is an imaging technique used to visualize the structure and function of tissues and organs in the body. Magnetic resonance imaging is physically based on the principles of nuclear magnetic resonance. As a rule, a strong magnetic field is superimposed with an alternating magnetic field, wherein the alternating field is formed in such a way that it leads to a resonant excitation of (certain) atomic nuclei. This resonant excitation may be detected in a receiving coil.

The brightness of different tissue types in an image is influenced by their relaxation times and the content of excited atomic nuclei. Which of these parameters dominates the image contrast is influenced by the choice of pulse sequence.

Different sequences of images are usually taken. It is also common for contrast agents to be administered (intravenously) for certain examinations. In contrast-enhanced MRI images, contrast agents lead to the signal intensity of certain regions being increased in the corresponding image. The signal-enhanced regions have a significantly higher signal intensity than the corresponding regions in the native MRI images.

Nowadays, contrast agents are an essential component in the diagnosis of MRI images. At the same time, contrast agents are suspected of being harmful to health (e.g. due to the gadolinium they contain) and cause high costs in the healthcare system. Excreted contrast agents also pose a problem for bodies of water.

Although there are newer developments towards other contrast agents that may be administered in a lower dose due to their chemical structure, these are more expensive.

Previous approaches that attempted to reduce the contrast agent administration and to process the resulting data using artificial intelligence were only partially successful. Current limitations are in particular the representation of multiple or small pathological contrast agent accumulations, false-positive contrast agent signals and the lack of generalizability.

The processing speed of complex networks is usually low, meaning that the effort required to calculate the data is high and therefore time-consuming. To compensate for this, processing is carried out at slice image level in previous approaches. However, this means that the corresponding networks may only deliver good quality results at slice image level. If the data of all data points is also processed, artifacts often occur, so that disadvantages may also arise here.

The prior art provides the US patent application US 2019/108 634 A1 as well as the article “CONTRAST-ENHANCED BRAIN MRI SYNTHESIS WITH DEEP LEARNING: KEY INPUT MODALITIES AND ASYMPTOTIC PERFORMANCE” by the authors A. Bône et al. published in 2021 IEEE 18th INTERNATIONAL SYMPOSIUM ON BIOMEDICAL IMAGING (ISBI), IEEE, Apr. 13, 2021, pages 1159-1163, DOI: 10.1109/ISBI48211.2021.9434029.

These approaches to contrast agent signal enhancement using artificial intelligence aim to predict the T1-weighted image with full contrast agent administration as pixel-accurately as possible. An essential problem when attempting pixel-accurate prediction is the associated need to also predict the noise of the T1-weighted image with full contrast agent administration. By using this image as a reference, existing AI models are therefore confronted with the problem of transferring the inherently present and possibly highly pronounced noise from the input data into a new noise instance (for the generated image). Since noise signals are random, such a mapping may only be learned to a limited extent in practice. As a result, false-positive contrast enhancement signals are hallucinated from noise in the aforementioned AI-based approaches or an oversmooth output image is generated.

### PROBLEM

Proceeding from this, it is an objective of the invention to provide an improvement that allows contrast agents of any kind to be reduced without any perceptible loss of information.

### BRIEF DESCRIPTION OF THE INVENTION

The problem is solved by a device for providing MRI images relating to at least one part of a patient's body with reduced contrast agent administration according to claim 1.

The problem is also solved by a method for providing MRI images relating to at least one part of a patient's body with reduced contrast agent administration according to claim 11.

The problem is also solved by a computer program product and the use of methods and devices according to the invention.

Further advantageous embodiments are the subject of the various dependent claims, the figures and the description.

### BRIEF DESCRIPTION OF THE FIGURES

The invention is explained in greater detail below with reference to a drawing and exemplary embodiments. The drawing is a schematic representation and is not to scale. The drawing does not limit the invention in any way.

The drawing shows:

FIG. 1-4 a schematic representation of method aspects according to embodiments of the invention,

FIG. 5-14 exemplary MRI images for use in embodiments of the invention or obtained in methods according to embodiments of the invention,

FIG. 15 a schematic representation of device aspects according to embodiments of the invention, and

FIGS. 16 and 17 further schematic representations of aspects according to embodiments of the invention.

### DETAILED DESCRIPTION OF THE INVENTION

In the following, the invention will be described in greater detail with reference to the figures. It should be noted that different aspects are described, each of which may be used individually or in combination. In other words, each aspect may be used with different embodiments of the invention, unless explicitly presented as a pure alternative.

Furthermore, for the sake of simplicity, only one entity is generally referred to below. Unless explicitly stated, however, the invention may also comprise several of the entities concerned. In this respect, the use of the words “a”, “an” and “one” is only to be understood as an indication that at least one entity is used in a simple embodiment.

Insofar as methods are described below, the individual steps of a method may be arranged and/or combined in any order, unless the context explicitly indicates otherwise. Furthermore, the methods may be combined with one another, unless expressly indicated otherwise.

Data with numerical values are generally not to be understood as exact values, but also include a tolerance of +/−1% up to +/−10%.

Insofar as standards, specifications or the like are named in this application, at least the standards, specifications or the like applicable on the filing date are always referred to. This means that if a standard/specification etc. was updated or replaced by a successor, the invention is also applicable to this.

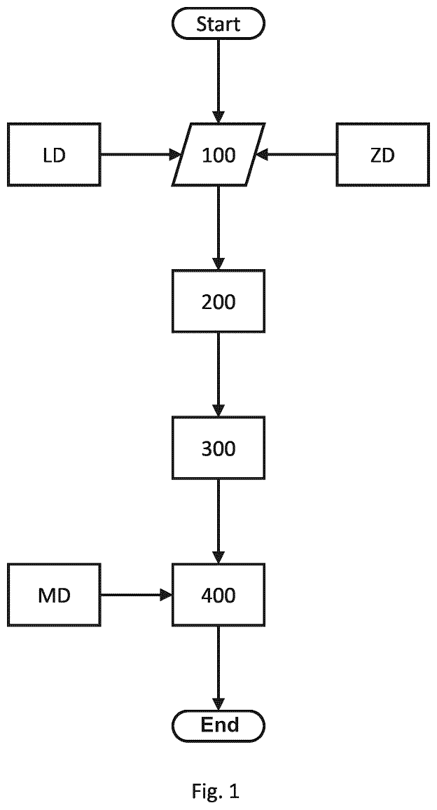

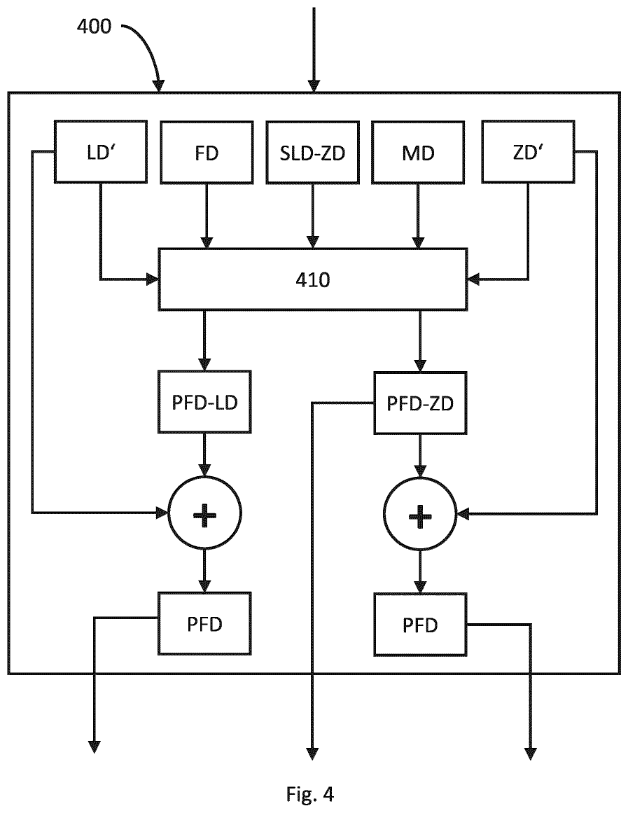

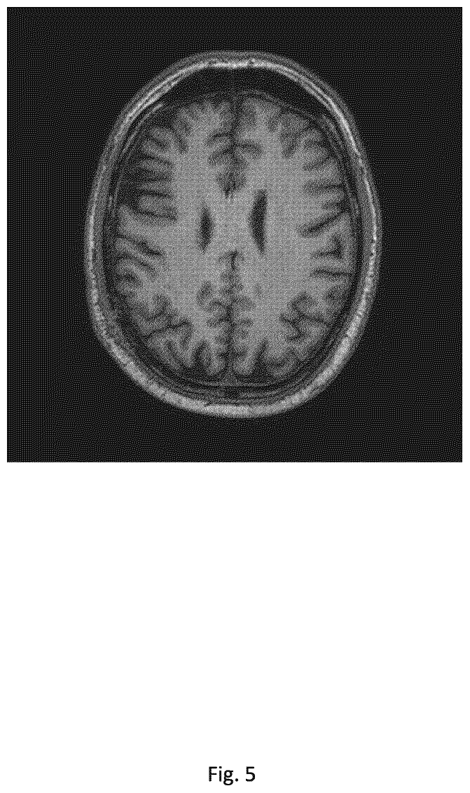

FIGS. 1 to 4 and 15 to 17 show aspects relating to various embodiments. FIGS. 5 to 14, on the other hand, show exemplary MRI images, which are used for explanation below.

In the following, reference signs with and without apostrophes are used in the description/figures. The addition of an apostrophe indicates that (optional) preprocessing, e.g. rescaling/standardization/registration etc. has taken place. If such pre-processing is not necessary, e.g. because the MRI image already has the same size, it is assumed below that reference signs with and without apostrophe are to be used synonymously.

A device 1 according to the invention for providing MRI images relating to at least one part of a patient's body with reduced contrast agent administration comprises at least input means for obtaining MRI images relating to at least one part of a patient's body without contrast agent administration, and input means for obtaining MRI images relating to at least the part of the patient's body with contrast agent administration, wherein the contrast agent administration allowed for the body part is reduced by at least 50% compared to a conventional MRI image.

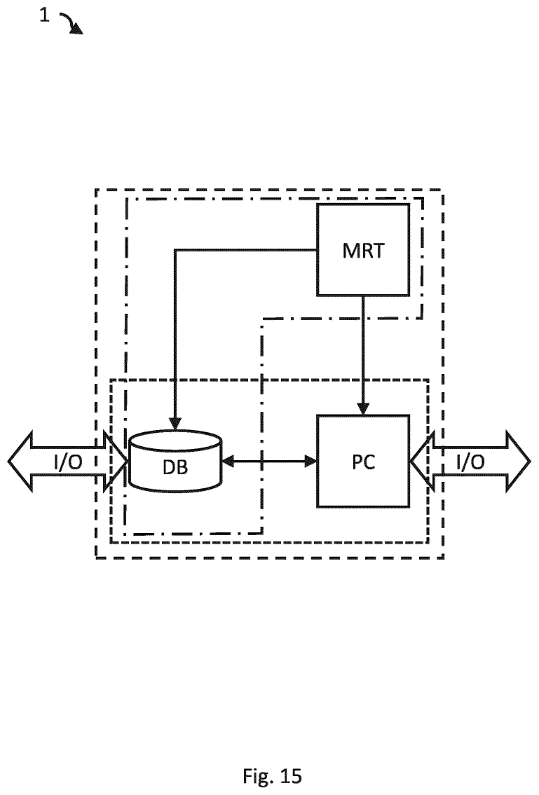

Without limiting the generality, the device 1 may, for example, be embodied in a PC that is programmed. Likewise, as indicated in FIG. 15, the device 1 may also be integrated into an MRI device. It is also possible for the device 1 to contain a data memory DB in addition to a PC. For example, processing according to the method of the invention may also be offered as a service by means of a suitable optional interface I/O (e.g. an interface to the Internet). By means of such an interface I/O, data may also be provided from or to a data memory DB and/or for retrieval by the device 1 or the PC as well as for retrieval and/or provision from/to an external source, e.g. a remote MRI device or an external display device—e.g. for diagnosis/reporting.

In other words, the interfaces I/O may be understood as input means to a device 1 according to the invention, just like a direct connection (via a specific interface and/or a local network).

The device 1 according to the invention further comprises means for image registration of the MRI images without contrast agent administration and of the MRI images with contrast agent administration, wherein the means for image registration operate in three-dimensional space.

These means may also be programmed in a device 1.

The device 1 according to the invention further comprises means for creating at least one subtraction image from the comparison of image-registered MRI images without contrast agent administration and image-registered MRI images with contrast agent administration.

These means may also be programmed in a device 1.

The device 1 according to the invention further comprises means for contrast enhancement based on the subtraction image, wherein the means for contrast enhancement provide both enhancement and artifact reduction based on a trained neural network by means of a nonlinear transformation.

These means may also be programmed in a device 1.

In a corresponding manner, a method according to the invention for providing MRI images relating to at least one part of a patient's body with reduced contrast agent administration comprises a step 100 of obtaining MRI images relating to at least one part of a patient's body without contrast agent administration ZD (Zero Dose) and a step 100 of obtaining MRI images relating to at least the part of the patient's body with contrast agent administration LD (Low Dose), wherein the contrast agent administration allowed for the body part is reduced by at least 50% compared to a conventional MRI image.

The method according to the invention further comprises a step 200 of performing an image registration of the MRI images without contrast agent administration and of the MRI images with contrast agent administration, wherein the means for image registration operate in three-dimensional space.

Furthermore, the method according to the invention has a step 300 of creating at least one subtraction image SD from the comparison of image-registered MRI images without contrast agent administration and image-registered MRI images with contrast agent administration.

Furthermore, the method according to the invention has a step 400 of providing a contrast enhancement based on the subtraction image SLD-ZD (Subtraction Low Dose and Zero Dose), wherein both an enhancement and an artifact reduction are provided based on a trained neural network.

The image registration may be configured in different ways. In particular, elastic image registration as well as rigid body registration may be provided. In one embodiment of the invention, the image registration means provide rigid body registration in three dimensions. Similarly, in a method according to the invention, a rigid body registration 210 in three dimensions may also be provided in the image registration step 200.

Preferably, the rigid body registration 210 in three dimensions is a multiscale rigid body registration. Further optionally, a non-linear optimization method with step size control may be used for optimization.

The image registration 200 is preferably applied to all images and is also preferably retained for the rest of the processing.

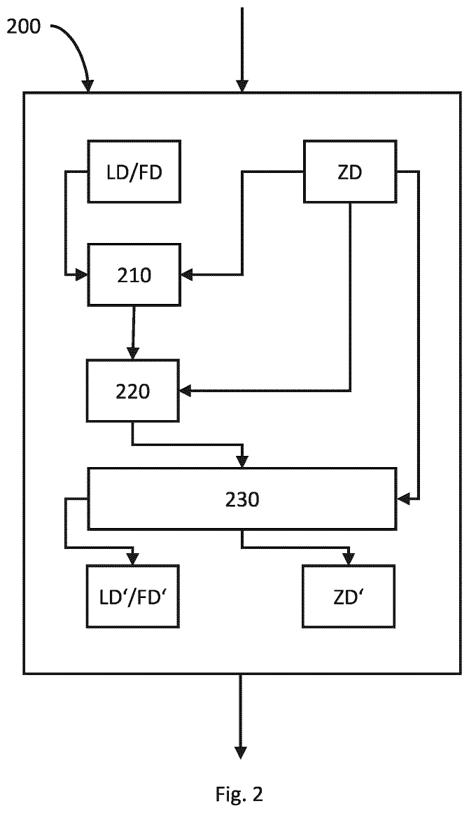

As is visible from FIG. 2, the image registration step 200 may also include further steps. For example, a radiometric registration step 220 and/or a standardization step 230 may be provided.

By means of the standardization in step 230, the images may be standardized so that the signal intensities of the regions not highlighted by the contrast agent approximately match. This may also be understood as an adjustment of the gray scaling.

In particular, the standardization of the intensities may be a Student t-standardization or a Nyul standardization (see e.g. L. G. Nyul, J. K. Udupa and Xuan Zhang, “New variants of a method of MRI scale standardization,” in IEEE Transactions on Medical Imaging, vol. 19, no. 2, pages 143-150, February 2000, doi: 10.1109/42.836373), but without excluding the use of other standardizations.

In particular, radiometric registration 220 may provide that regions with contrast agent enhancement (e.g. from a comparison of images with contrast agent FD (Full Dose), LD, FD′, LD′ and images without contrast agent ZD of the same region or from the respective (co-registered) subtraction images SLD-ZD/SFD-ZD (subtraction Full Dose and Zero Dose) remain excluded (masked) from this. However, this may also be estimated using a high quantile, e.g. a 95% quantile of the intensity, of MRI images with contrast agent FD or SLD-ZD, SFD-LD. The functional may be a rescaled Student t-function. In addition, radiometric registration may use methods of robust statistics to minimize sensitivity to outliers.

In one embodiment of the invention, the device 1 further comprises means for interpolation so that MRI images of different resolutions may be interpolated to a common resolution prior to further processing. In a corresponding manner, the method may also preferably comprise a sub-step of interpolation in step 200. In principle, this interpolation step may be arranged anywhere within the sub-steps. This means that the same image size may be assumed for all subsequent steps, so that processing may be standardized to run in parallel or sequentially if different MRI images pass through the same steps. This also facilitates further processing in that, for example, addition and subtraction may be carried out at pixel level, whereas this would not be easily possible with images of unequal size.

In particular, the interpolation may provide for MRI images of different resolutions to be transferred to a common isotropic resolution.

In step 400, a suitably trained neural network may be used in a step 410 to generate a de-noised contrast-enhanced difference image PFD-ZD or PFD-LD (Predicted Full Dose minus Zero Dose or Predicted Full Dose minus Low Dose) from the previously calculated subtraction image SLD-ZD and optionally (either) the MRI image without contrast agent ZD/ZD′ or the MRI image with low contrast agent dose LD/LD′. This de-noised contrast-enhanced difference image PFD-ZD or PFD-LD may optionally be added to the MRI images without contrast agent ZD/ZD′ or to the MRI images with a low contrast agent dose LD/LD′, so that only the amplified contrast agent enhancement signal is transmitted, with any associated artifact reduction.

In embodiments of the invention, it may also be provided that at least one metadatum MD is also used to provide a contrast enhancement 400. This may be provided at the beginning of the method, or may be entered, determined or transmitted at any other time prior to use.

In particular, the at least one metadatum (MD) may be selected from a group comprising device identification, field strength(s) used during the measurement, contrast agent used during the measurement, contrast agent relaxivity, contrast agent administration used during the measurement (absolute and/or relative amount), patient weight, patient age, patient height, patient gender, patient status (e.g. pre-/post-operative) as well as statistical information from the SLD-ZD subtraction image. The use of patient-specific data represents a further improvement, as the contrast agents administrations have so far been insufficiently patient-specific, so that, for example, the patient's weight is taken into account, but not whether the patient is particularly heavy due to their bone structure or whether their physical development has a different proportion of soft tissue. Likewise, by using metadata (in particular e.g., field strength, device, contrast agent, contrast agent dose, contrast agent volume, etc.), the neural network may be conditioned to various heterogeneous influencing factors and thus adaptation to changed framework conditions is possible without having to retrain the network.

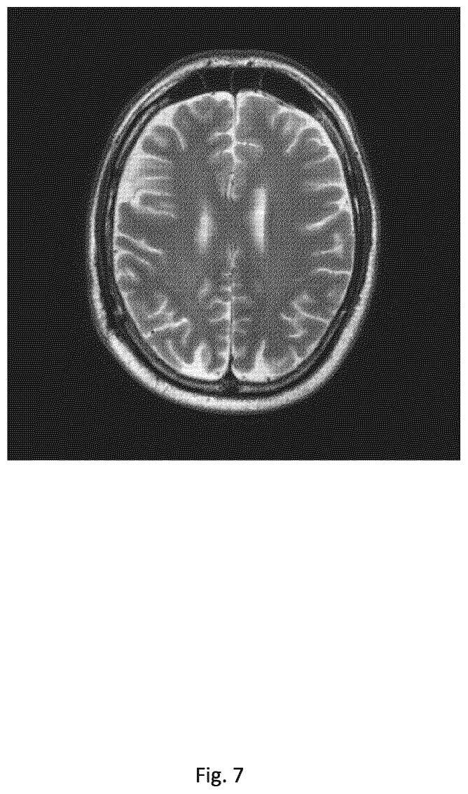

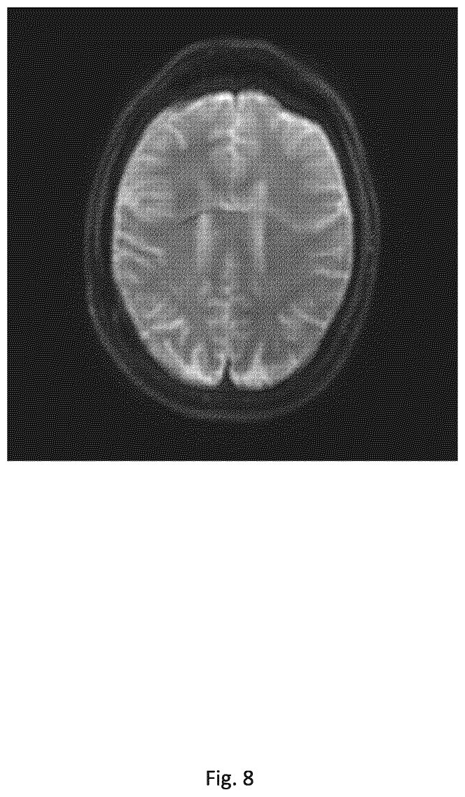

In other words, in a method/device according to the invention, a three-dimensional, isotropic T1-weighted MRI image (FIG. 5) and, if necessary, a T2-weighted MRI image (FIG. 7) and a diffusion-weighted image without contrast agent administration (FIG. 8) are first preferably acquired by an MRI device or read out from a data memory DB.

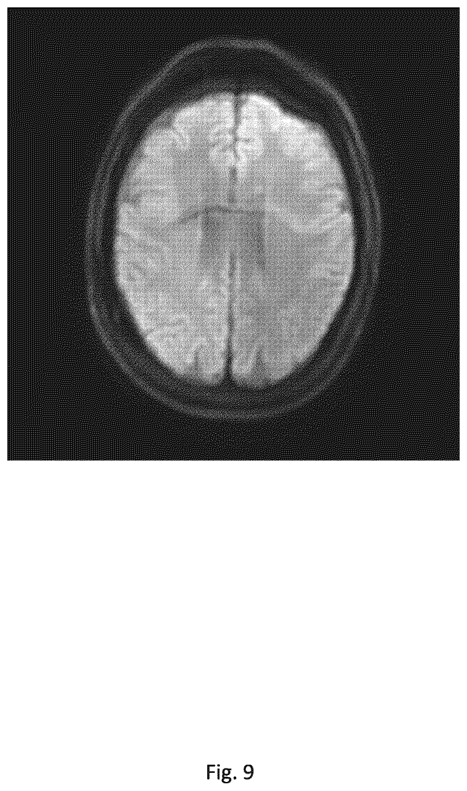

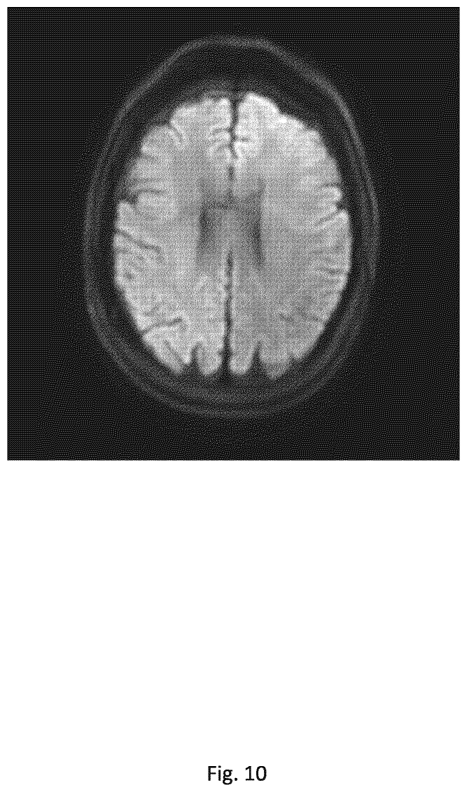

FIGS. 8-10 show, for example, diffusion-weighted MRI images corresponding to different protocols, e.g. b-value: 0 (FIG. 8), 500 (FIGS. 9) and 1000 (FIG. 10).

As contrast agents are excreted slowly compared to the duration of an MRI scan, MRI scans are taken without contrast agents at the beginning.

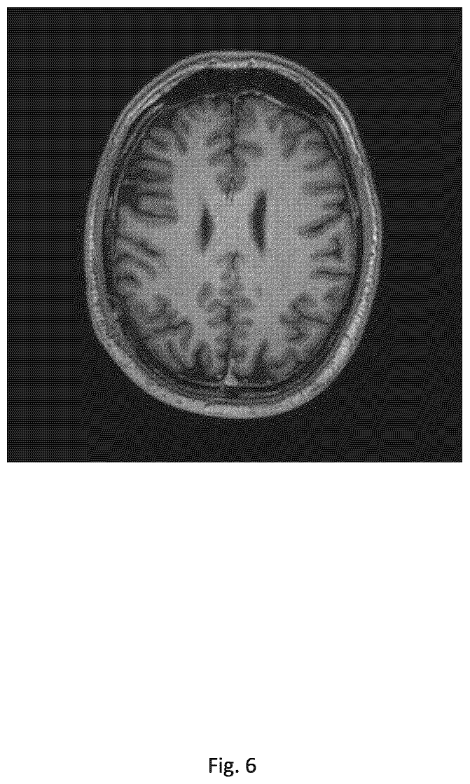

Acquisition is then performed from an MRI device or by reading from a data memory DB of another T1-weighted MRI image (FIG. 6) that meets the above criteria after administration of a significantly reduced dose of the contrast agent.

Here it is sufficient—especially experimentally—to reduce the contrast agent administration to a range of around 10%-33% of the allowable contrast agent administration. These MRI images are also referred to as low-dose LD images.

Preferably, the MRI images are standardized after receipt so that the signal intensities of the regions not highlighted by the contrast agent approximately match. Here, for example, a functional may be minimized that describes the distance between the images to be standardized (robustly). The functional may be a rescaled Student t-function. Regions of contrast center enhancement may be masked out. Such regions may be calculated on the basis of the 95% quantile of the intensities of the contrast agent images.

Before further processing, the MRI images, e.g., the (isotropic) T1-weighted images without contrast agent administration (FIG. 5) as well as the (isotropic) T1-weighted images with contrast agent administration (FIG. 6) may be fed to an image registration in three-dimensional space, so that a-preferably exactly-rectified spatial orientation is given.

The T2- and diffusion-weighted images may also be registered in three-dimensional space without contrast agent.

The method used is preferably a multiscale rigid body registration, wherein a conjugate gradient method with a line search condition may be used for optimization as an exemplary non-linear optimization method with step size control.

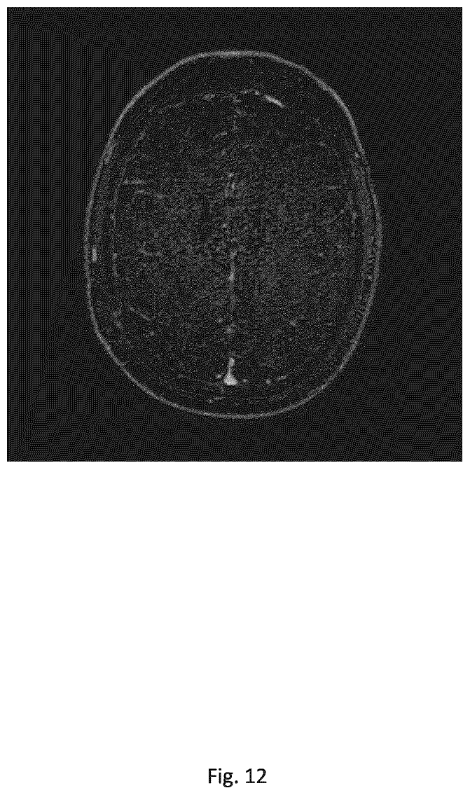

A subtraction image SLD-ZD (FIG. 12) of the two (image-registered) MRI images may be generated from the image-registered (isotropic) T1-weighted images without contrast agent administration (FIG. 5)—ZD and the (isotropic) T1-weighted images with low contrast agent administration (FIG. 6—LD), in which the signals (and possibly artifacts) and noise generated by the contrast agent are substantially visible.

A fixed non-linear transformation may then be applied to the subtraction image (FIG. 12) in order to increase the contrast signal and reduce the noise. For example, the function f(x)=max(x,c) may be used here, in which all pixel values below a threshold c are set to this value. A fixed non-linear transformation may also be a statistical analysis, for example, which may be used to map the noise in the subtraction image to zero.

Using a neural network with three-dimensional convolution, the signals on the transformed subtraction image may be amplified and at the same time any existing artifacts and noise may be reduced or eliminated. For example, the calculated (and transformed) subtraction image SLD-ZD may be used as input for the neural network. Optionally, the T1-weighted images with contrast agent administration LD/LD′ and/or without contrast agent administration ZD/ZD′ and/or T2-weighted images and/or diffusion images may also be used. Further metadata MD or further images may also be optionally entered into the neural network. At the output of the neural network, a de-noised three-dimensional subtraction image PFD-ZD or PFD-LD is provided, in which the regions highlighted by the contrast agent are more clearly recognizable because it substantially only contains the enhancement signal of the contrast agent as positive contributions and all non-enhancing regions are substantially mapped to zero. The PFD-ZD subtraction image approximates the standard subtraction image previously used for diagnostic purposes.

The neural network is preferably a feedforward network consisting of, for example, preferably seven consecutive convolutional blocks, wherein the first three (front) blocks may be used, for example, to reduce the resolution and the last (back) three blocks may be used, for example, to increase the resolution so that the original resolution is obtained after the final block. In particular, two blocks of the same resolution may be linked by residual connections. To support multiple resolutions, a correspondingly lower resolution input image may also be added in the second block. For example, metadata MD, such as contrast agent dose (absolute and/or relative), contrast agent type, field strength(s), device used, coil(s) used, relaxivity and patient data such as patient height, patient weight, etc. may be used as optional inputs.

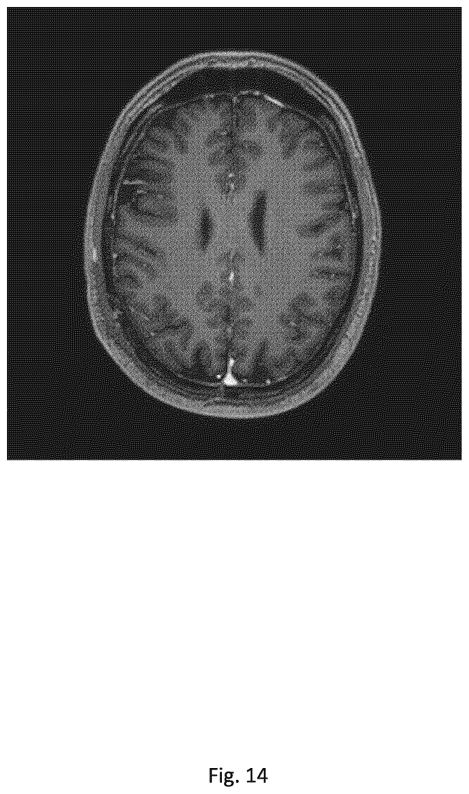

For better anatomical delineation and morphological classification, a T1-weighted MRI image PFD (Predicted Full Dose) may be generated by adding the noise-free (de-noised) subtraction image PFD-ZD to the T1-weighted native MRI image ZD/ZD′ (FIG. 14), which is similar to the MRI image with full contrast agent administration FD/FD′ (in terms of contrast enhancement behavior).

Alternatively, a T1-weighted MRI image PFD may be generated by adding the noise-free subtraction image PFD-LD to the T1-weighted low-dose images LD/LD′.

As may already be seen, a neural network is also used in the context of the invention. This must be suitably trained before use.

To complete the teaching according to the invention, the training process will now be briefly discussed.

In addition to the images without and with reduced contrast agent administration described above, T1-weighted MRI images—preferably similar three-dimensional, isotropic images—with the full dose of contrast agent are also used for training.

The data obtained are then standardized-as described above-so that the signal intensities of the regions not highlighted by the contrast agent approximately match, and image registration is performed.

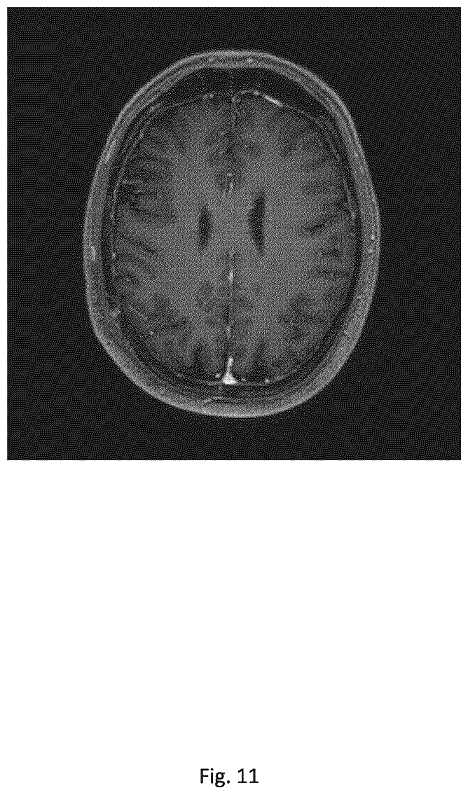

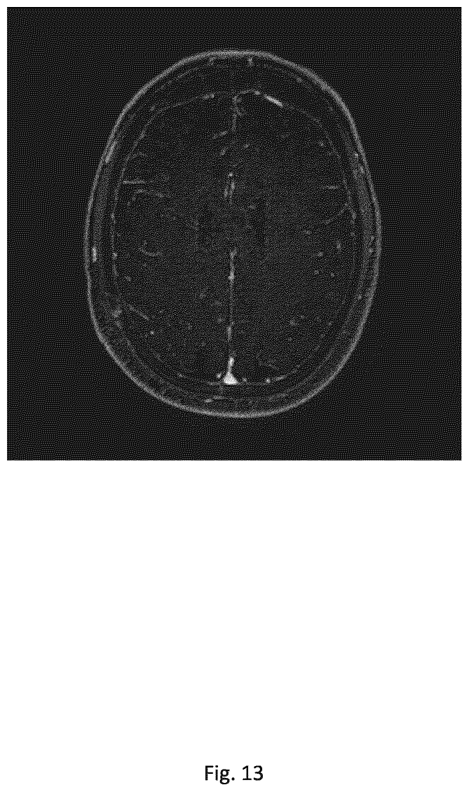

However, two subtraction images are now calculated. One subtraction image SFD-ZD (subtraction full dose minus zero dose, FIG. 13) is based on the difference between the registered MRI image with full contrast agent administration FD/FD′ (FIG. 11) and the registered MRI image without contrast agent administration ZD/ZD′, while the other subtraction image SLD-ZD (FIG. 12) is determined as before using the registered MRI image with reduced contrast agent administration. This means that the process 200 may be the same for both subtraction images.

As before, the native T2 and/or diffusion-weighted MRI images may also be registered in three-dimensional space.

As before, a non-linear transformation may be applied to each of the two subtraction images in order to obtain the contrast signal and reduce the noise at the same time.

Using the subtraction images obtained, it is now possible to train the neural network so that the calculated contrast-enhanced subtraction image PFD-ZD differs as little as possible from the de-noised subtraction image RFD-ZD (Reference Full Dose minus Zero Dose) of the registered MRI images without contrast agent administration and the registered MRI images with full contrast agent administration. This means that the output of the neural network PFD-ZD, i.e., the error-corrected computer-generated subtraction image, is compared with the de-noised reference image RFD-ZD in a predefined loss function, or PFD-LD with RFD-LD. The loss function may, for example, be the sum of three functions: an L1 loss, a more heavily weighted L1 loss, which is only applied in regions of the contrast agent, and a more heavily weighted L1 loss, wherein the weight may be determined by the Laplace operator applied to a smoothed image.

In the context of this invention, data from a large number of patients from the period 2021 to 2023 from different radiological centers and clinics in Germany and from different MRI devices with 1.5 Tesla and 3 Tesla from the manufacturers Siemens and Philips as well as different contrast agents (Dotarem from Guerbet, Gadovist from Bayer, Prohance from Bracco, Clariscan from GE Healthcare, etc.) were used in the manner described above to train the neural network. In particular, MRI images of the skull of the respective patients were taken, wherein, in addition to images without contrast agent, images with a reduced contrast agent administration, wherein the contrast agent administration approved for the body part was reduced by at least 50%—usually to 33%—compared to a conventional MRI image, and images with the contrast agent administration approved for the body part were recorded. First, images were taken without contrast agent, then images were taken with a low contrast agent administration, and finally images were taken with the full contrast agent administration, i.e. after administration of the remaining dose (difference between full dose and lower dose). The training dataset may contain training datasets on severe pathological sections (e.g. micrometastases, contrast-free accumulations). In order to provide better training, these training data sets with severe pathological sections may be weighted more heavily. In an exemplary trained neural network, these training data sets with severe pathological sections, for example, make up a proportion of around 50%.

The reduction in the amount of contrast agent is achieved by computer-assisted amplification of the signal generated by a lower dose of contrast agent in the MRI images. The method uses a deep learning network for image-to-image regression with, for example, a pre-contrast image and a low contrast image or a subtraction image SLD-ZD as input and with a full contrast image or de-noised subtraction image PFD-ZD/PFD-LD calculated by the neural network as output.

For better anatomical delineation and morphological classification, a T1-weighted MRI image PFD may be generated by adding the de-noised subtraction image PFD-ZD/PFD-LD to the T1-weighted native MRI image ZD/ZD′ or to the T1-weighted MRI image with low dose LD/LD′, which is similar to the MRI image with full contrast agent dose in terms of contrast enhancement.

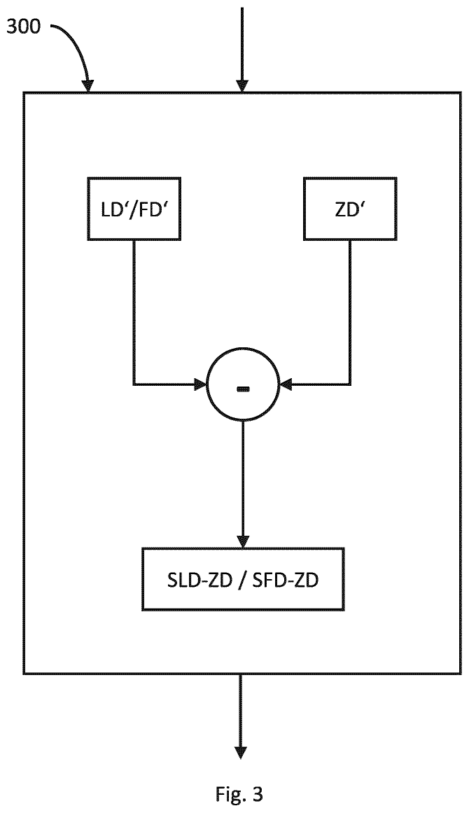

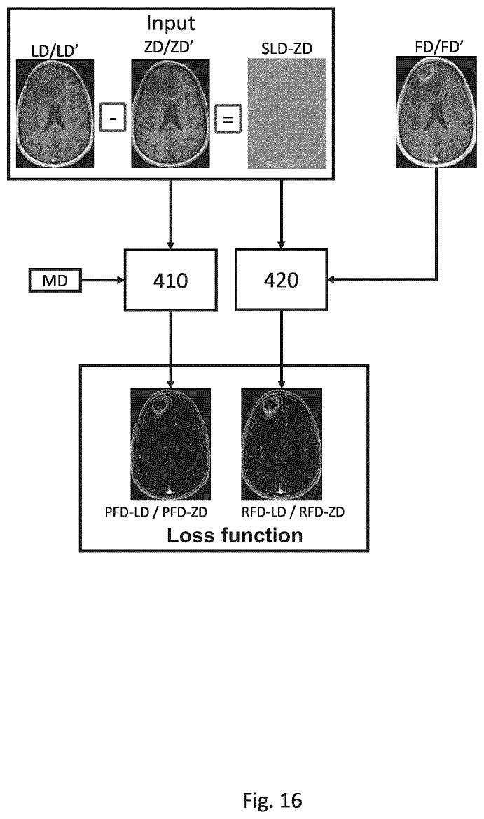

FIG. 16 shows a schematic representation of how the invention works. The invention fundamentally works with subtraction images (see also FIG. 3): Subtraction images SLD-ZD of images with reduced contrast agent administration LD/LD′ in relation to images without contrast agent dose administration ZD/ZD′, subtraction images SFD-ZD of images with full contrast agent administration FD/FD′ in relation to images without contrast agent administration ZD/ZD′, as well as subtraction images SFD-LD of images with full contrast agent administration FD/FD′ in relation to images with reduced contrast agent administration LD/LD′.

The subtraction images contain intensity changes caused by the contrast agent, but hardly any anatomical structures. In addition to the intensity changes caused by the contrast agent, there is also noise, which makes it difficult to extract and amplify the contrast enhancement.

The neural network 410 may calculate a prediction of the de-noised subtraction image with full contrast agent administration PFD-ZD or the de-noised subtraction image between full and reduced contrast agent administration PFD-LD from the subtraction image SLD-ZD and, if applicable, the images without contrast agent administration ZD/ZD′ or the images with reduced contrast agent administration LD/LD′, wherein metadata MD may also be taken into account (e.g. field strength, contrast agent, relaxivity, patient data, etc.).

The model of the neural network 410 only has to calculate the change (noise & contrast enhancement) from the subtraction image SLD-ZD to either the de-noised subtraction image RFD-ZD or RFD-LD in order to be able to describe an equivalent contrast enhancement behavior.

In order to avoid predicting the noise signal of the MRI image with full contrast agent administration FD/FD′ and thereby simplify the training of the neural network 410, the reference image in the training is a de-noised subtraction image RFD-ZD or RFD-LD, depending on whether the subtraction image generated by the network is added to images without contrast agent administration ZD/ZD′ or those with reduced contrast agent administration LD/LD′. This is advantageous, as both the images with full contrast agent administration FD/FD′ and the subtraction images formed from them are subject to very high levels of noise and are therefore unsuitable as a reference.

The reference image RFD-ZD or RFD-LD is calculated from the images without contrast agent administration ZD/ZD′, with reduced contrast agent administration LD/LD′ and full contrast agent administration FD/FD′ in step 420 so that it is as noise-free as possible.

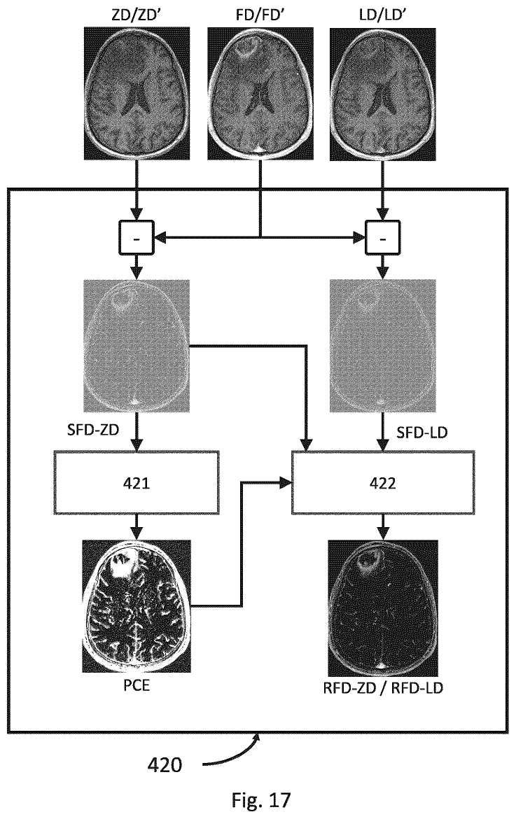

In the context of the invention, the reference image RFD-ZD or RFD-LD, see FIG. 17, is therefore calculated for the training. First, in step 421, a probability of contrast enhancement (PCE) is calculated for each pixel from the subtraction image SFD-ZD using a machine learning model (e.g., convolutional neural network, Gaussian mixture model, Markov random field, etc.). With this probability, pixels with a contrast enhancement may be distinguished from pixels with noise and thus the corresponding subtraction image SFD-ZD or SFD-LD may be freed from noise in step 422 in order to obtain the de-noised reference image RFD-ZD or RFD-LD.

By using the de-noised reference image as ground truth, the neural network 410 according to the invention is configured to generate an image that contains only the missing contrast agent enhancement (see FIG. 16).

The use of the noise-free reference image as ground truth of the neural network model 410 according to the invention has significant advantages over the use of the MRI image with full contrast agent administration FD:

1. The neural network 410 is focused on the prediction of signal increases actually caused by contrast agents and is not misguided by noise in the ground truth.

2. The synthesized image with full contrast agent administration (PFD) is created by adding either the image without contrast agent administration ZD/ZD′ with the prediction PFD-ZD or the image with reduced contrast agent administration LD/LD′ with the prediction PFD-LD. Thus, the noise in the synthesized image PFD corresponds to the noise in the ZD/ZD′ or LD/LD′image. This makes hallucination of the contrast agent signal very unlikely.

The method according to the invention or device according to the invention may use three-dimensional data throughout. Furthermore, rigid body registration in three dimensions is preferably used. In addition, the invention is based on subtraction images in the calculation. Preferably, only the highlighted regions (regions with contrast agent signal) are processed, while the rest of the images remain unchanged. The neural network exclusively enhances and improves these subtraction images, preferably taking into account all available sequences (native T1, low dose T1, T2, diffusion). In addition to the T1 sequences, the neural network may obtain additional information from the T2 and diffusion sequences.

Without limiting the generality, the device 1 may, for example, be embodied in a programmed PC. Likewise, as indicated in FIG. 15, the device 1 may also be integrated into an MRI device. It is also possible for the device 1 to contain a data memory DB in addition to a PC. For example, processing according to the method of the invention may also be offered as a service by means of a suitable interface I/O (e.g. an interface to the Internet). By means of such an interface I/O, data may also be provided from or to a database for retrieval by the device 1 or the PC as well as for retrieval from an external source, e.g., a remote MRI device.

In other words, the interfaces I/O may be understood as input means to a device 1 according to the invention, just like a direct connection (via a specific interface and/or a local network).

Without limiting the generality of the invention, the invention may allow an approved contrast agent administration (e.g., a gadolinium-containing contrast agent) to be reduced from, e.g., 0.1 mmol/kg to a significantly lower proportion of, e.g., 0.033 mmol/kg in regular use. This applies in particular to preparations containing gadopentetate dimeglumine as well as preparations containing gadobutrol.

In particular, without limiting the generality, the contrast agent may be reduced to 50% to 1%, in particular 35% to 5%, in particular 35% to 30%, and in particular 20% to 5% compared to an approved contrast agent administration, without compromising the quality, since the neural network provides contrast enhancement.

Furthermore, the invention may in particular also be embodied in a computer program product for the information technology configuration of a computer PC for processing steps of a method according to the invention. This computer program product may, for example, be provided on a data carrier or as a downloadable signal sequence.

In contrast to the prior art, the use of subtraction images as input to the neural network may greatly reduce the susceptibility to artifacts, so that only regions with a contrast distinction are fed for amplification. The output of subtraction images with optional addition to native MRI images places the focus on the contrast agent signal to be amplified and thus avoids the problems of previous approaches described above with regard to the prediction of noise behavior and the associated limitations. The use of data in 3D space also ensures that all data is treated equally. Rigid body registration in three dimensions also ensures that all data may be processed precisely, so that three-dimensional reconstructions are also easily possible. In addition, the invention also allows the integration of other MRI images and other metadata, which may lead to further improvements.

1. A device for providing MRI images relating to at least one part of a patient's body with contrast agent administration, comprising
input means for obtaining MRI images relating to at least one part of a patient's body without contrast agent administration,
input means for obtaining MRI images relating to at least the part of the patient's body with a first contrast agent administration,
means for image registration of the MRI images without contrast agent administration and the MRI images with contrast agent administration,
means for creating at least one subtraction image from the comparison of image-registered MRI images without contrast agent administration and image-registered MRI images with contrast agent administration,
means for contrast enhancement based on the subtraction image and the image-registered MRI images without contrast agent administration or the MRI image with the first contrast agent administration, wherein the means for contrast enhancement on the basis of a trained neural network provide on the one hand an enhancement as well as an artifact reduction by means of a non-linear transformation, wherein the trained neural network has been trained at least partially using de-noised reference images as ground truth and wherein the means for contrast enhancement are set up to produce a de-noised contrast-enhanced difference image.

2. The device according to claim 1, characterized in that the de-noised reference images have been produced at least partially from subtraction images containing noise and based on a probability of a contrast agent-related signal enhancement calculated by means of a machine learning model for each of the subtraction images.

3. The device according to claim 1, characterized in that the first contrast agent administration is reduced by at least 50% relative to a second contrast agent administration, the second contrast agent administration corresponding to a conventional contrast agent administration allowed for an MRI image of the body part.

4. The device according to claim 1, characterized in that three-dimensional data is used throughout and the image registration means operate in three-dimensional space and provide rigid body registration in three dimensions.

5. The device according to claim 1, characterized in that the device further comprises means for interpolation, so that MRI images of different resolutions may be interpolated to a common resolution before further processing.

6. The device according to claim 5, characterized in that the means for interpolation have a standardization of the intensities.

7. The device according to claim 6, characterized in that the means for interpolation have at least one of a Student t-standardization of the intensities and a Nyul standardization of the intensities.

8. The device according to claim 1, characterized in that the neural network has three-dimensional convolutions.

9. The device according to claim 1, characterized in that the neural network takes into account different sequences selected from T1-weighted acquisition without contrast agent administration, T1-weighted acquisition with reduced contrast agent administration, T2-weighted acquisition, and diffusion-weighted acquisition.

10. The device according to claim 1, characterized in that the contrast-enhanced subtraction image is added to the image-registered MRI images without contrast agent administration.

11. The device according to claim 1, characterized in that the contrast-enhanced subtraction image is added to the image-registered MRI images with reduced contrast agent administration.

12. A method for providing MRI images relating to at least one part of a patient's body with reduced contrast agent administration, said method comprising the steps of
obtaining MRI images relating to at least one part of a patient's body without contrast agent administration,
obtaining MRI images relating to at least the part of the patient's body with a first contrast agent administration,
performing image registration of the MRI images without contrast agent administration and of the MRI images with the first contrast agent administration,
producing at least one subtraction image from the comparison of image-registered MRI images without contrast agent administration and image-registered MRI images with contrast agent administration,
providing a contrast enhancement based on the subtraction image and the image-registered MRI images without contrast agent administration or with reduced contrast agent administration, wherein an enhancement is provided on the basis of a trained neural network, wherein the trained neural network has been trained at least partially using de-noised reference images as ground truth and wherein a de-noised contrast-enhanced difference image is created.

13. The method according to claim 12, characterized in that the de-noised reference images have been produced at least partially from subtraction images containing noise and based on a probability of a contrast agent-related signal enhancement calculated by means of a machine learning model for each of the subtraction images.

14. The method according to claim 12, characterized in that the first contrast agent administration is reduced by at least 50% relative to a second contrast agent administration, the second contrast agent administration corresponding to a conventional contrast agent administration allowed for an MRI image of the body part.

15. The method according to claim 12, characterized in that three-dimensional data is used throughout and the image registration means operate in the three-dimensional space and provide rigid body registration in three dimensions.

16. The method according to claim 12, characterized in that it comprises an approved contrast agent administration of 0.1 mmol/kg.

17. The method according to claim 12, characterized in that the first contrast agent administration is 50% to 1%, in particular 35% to 5%, in particular 35% to 30%, and in particular 20% to 5% compared to a second contrast agent administration corresponding to an approved contrast agent administration.

18. The method according to claim 12, characterized in that the provision of a contrast enhancement is also provided on the basis of at least one metadatum.

19. The method according to claim 18, characterized in that the at least one metadatum is selected from the group comprising a device identification, field strength(s) used in the measurement, contrast agent used in the measurement, contrast agent administration used in the measurement (absolute and relative), weight of the patient, age of the patient, height of the patient, sex of the patient, status of the patient (e.g., pre-/post-operative).

20. The method according to claim 12, characterized in that a standardization step for standardizing intensities is further provided.

21. The method according to claim 20, characterized in that the standardization step comprises at least one of a Student t-standardization of the intensities and a Nyul standardization of the intensities.

22. The method according to claim 12, characterized in that the neural network has three-dimensional convolution.

23. The method according to claim 12, characterized in that the neural network takes into account different sequences selected from native T1, low dose T1, T2, diffusion.

24. The method according to claim 12, characterized in that the contrast-enhanced subtraction image is added to the image-registered MRI images without contrast agent administration.

25. The method according to claim 12, characterized in that the contrast-enhanced subtraction image is added to the image-registered MRI images with reduced contrast agent administration.

26. A computer program product for the information technology configuration of a computer (PC) for processing steps of a method according to claim 12.

27. (canceled)
